(19) United States
(12) Patent Application Publication
(10) Pub. No.: US 2023/0375755 A1
(43) Pub. Date: Nov. 23, 2023

(54) MOISTURE-RESISTANT OPTICAL DEVICE AND METHOD OF MANUFACTURE

(71) Applicant: ams International AG, JONA (CH)

(72) Inventors: Sylvain GROSSMANN, Rüschlikon (CH); Olivier RIPOLL, Bern (CH); Sebastiano LAZZI, Zuerich (CH)

(73) Assignee: ams International AG, JONA (CH)

(21) Appl. No.: 18/042,615

(22) PCT Filed: Aug. 18, 2021
(86) PCT No.: PCT/EP2021/072971

§ 371 Date: Feb. 23, 2023

(30) Foreign Application Priority Data
Aug. 27, 2020 (GB) 2013471.4

(51) Int. Cl. G02B 1/18; H01S 5/183; G02B 3/00

(52) U.S. Cl. CPC G02B 1/18; H01S 5/18388; G02B 3/0075

(57) ABSTRACT

A moisture-resistant optical device comprises a microlens array (MLA) formed from a first material defining a plurality of associated recesses; and a moisture-resisting layer of a second material, formed on the MLA and filling the associated recesses. An associated method of manufacture is also disclosed.

### CROSS-REFERENCE TO RELATED APPLICATIONS

The present application is the national stage entry of International Patent Application No. PCT/EP2021/072971, filed on Aug. 18, 2021, and published as WO 2022/043163 A1 on Mar. 3, 2022, which claims the benefit of priority of Great Britain Patent Application No. 2013471.4, filed on Aug. 27, 2020, the disclosures of all of which are incorporated by reference herein in their entireties.

### TECHNICAL FIELD OF THE DISCLOSURE

The disclosure relates to a moisture-resistant optical device and method of manufacture, particularly but not exclusively, to an illuminator including such an optical device, and method of manufacture.

### BACKGROUND OF THE DISCLOSURE

New features are being added to smart phones, tablets and other portable computing devices that include technologies to record two and three dimensional images, sense motion and/or gestures. Digital recording methods use various types of miniature illuminators, which may illuminate the subject to be recorded and/or interact with cameras to record dynamical events in three-dimensional regions. These illuminators can be of various forms and deliver different types of functions. Some illuminate a wide area with very short pulse Light Detection and Ranging (LIDAR) type measurements recording time of flight information. Other illuminators are pulsed or continuous wave (CW), and project structured light patterns onto a scene. The digital camera records an image and/or an image of the structured light pattern, and software algorithms are used to determine three-dimensional scene information from modifications in the patterned image. The illuminators may output infra-red light which is substantially invisible to the human eye.

Technologies that are suitable for miniature illuminators include high power vertical cavity surface emitting laser (VCSEL) devices, edge-emitting laser devices, and arrays of such devices. These devices can be pulsed with very fast rise times suitable for time-of-flight applications. They are small, but produce high power laser beams with efficient electro-optic conversion. However, various optical components (e.g., an optical diffuser) can be placed in the beam path to modify the beam properties for the specific application. Such optical components or devices may include a microlens array (MLA) of a type which is well known in the art, such as that shown in FIG. 1.

The optical output power of a bare VCSEL can, in some cases, be so high that it may cause damage to a person's eye or skin in the event the quality of the optical component is compromised. Thus, it is important to ensure that the high power laser illuminators meet laser safety regulations when operated in the portable computing devices. For example, the illuminator may be part of an assembly that, under normal operating conditions, maintains eye-safe operation by preventing a person from getting too close to the illuminator. However, in some cases, damage (e.g., cracks) to the optical structure that modifies the output beam for safe operation, or the presence of (water) moisture or chemical contamination on the optical structure, may result in safety hazards. Likewise, if the optical structure were to become detached or removed, safety could be compromised.

With regard to monitoring the quality of the optical device (and hence the safety of the illuminator of which it forms part), known optical devices may include an impact detector and/or moisture detector located at a surface of the optical device. Different types of such detector are known. One such detector includes a conductor, which undertakes a generally boustrophedonic (or meandering) path located at a surface of the optical device. The resistance between the ends of the conductor is measured—any significant change indicating that an impact has occurred or that moisture or chemical contamination is present on the device. Should this be detected, then the illuminator can be disabled or operated at reduced power to prevent any potential safety issue.

It is therefore an aim of the present disclosure to provide a moisture-resistant optical device that addresses one or more of the problems above or at least provides a useful alternative. For example, it may be desirable to provide an optical device which is less susceptible to the safety issues discussed above in relation to the presence of moisture or chemical contamination and/or due to impact. Furthermore, it may be desirable to provide an optical device and/or illuminator which does not require any impact detector and/or moisture detector. By removing the need for an impact detector and/or moisture detector this makes the manufacturing process for the optical device and/or illuminator more straightforward and less costly.

### SUMMARY

In general, this disclosure proposes to overcome the above problems by providing a moisture resistant layer. This arrangement prevents moisture or chemical contamination on the optical device from causing a potential safety hazard. For example, this arrangement prevents moisture or chemical contamination on the optical device from causing an eye safety hazard due to a reduced Field of Illumination (FOI) of the optical device.

According to one aspect of the present disclosure, there is provided a moisture-resistant optical device comprising: a microlens array (MLA) formed from a first material defining a plurality of associated recesses; and a moisture-resisting layer of a second material, formed on the MLA and filling the associated recesses.

The optical device may have defined optical properties; and a ratio between refractive indices of the second and first materials may be substantially the same as a ratio between air and a third material that would have been required to implement an MLA formed from the third material, in absence of the moisture-resisting layer, having said defined optical properties.

The defined optical properties of the optical device may be the far field beam profile or field of illumination (FOI) of the MLA.

The refractive index of the first material may be greater than the refractive index of the second material.

The plurality of micro-lenses of the MLA may define an MLA height and the MLA may further comprise an edge structure at a periphery of the MLA having an edge structure height which is equal to or greater than the MLA height. The moisture-resisting layer may be formed over the edge structure such that a total height of a moisture-resistant MLA portion of the optical device is equal to the edge structure height plus the thickness of moisture-resisting layer formed over the edge structure.

The moisture-resisting layer may form a planar surface of the optical device.

The MLA may be formed on a substrate. The substrate may be formed from glass.

The MLA may form part of a vertical cavity surface emitting laser (VCSEL) wafer formed of said first material, wherein at least one VCSEL emitter is formed in the VCSEL wafer.

There may be an array of VCSEL emitters. Each of the VCSEL emitters may be located beneath a corresponding micro-lens of the MLA.

An anode and cathode may be located at a base of the VCSEL wafer.

The optical device may not include any form of moisture detection.

The first material may include one or more of, or be formed of one of: Si, GaAs, Si3N4, SiO, SiN, or SiON.

The second material may include one or more of, or be formed of one of: an acrylic material or a modified epoxy resin.

The MLA may be formed by replication or nanoimprint.

The MLA may be written, for example by direct laser writing.

According to a second aspect of the invention there is provided an illuminator comprising an optical device according to any of the preceding claims. The optical device may be a diffuser.

The illuminator may be an infra-red illuminator. That is, it may emit infra-red light and include at least one infra-red light source.

According to a third aspect of the invention there is provided a method of manufacturing a moisture-resistant optical device, the method comprising: forming a microlens array (MLA), defining a plurality of associated recesses, from a first material; and forming a moisture-resisting layer of a second material on the MLA, said moisture-resisting layer filling the associated recesses.

The method may further comprise: determining a ratio between the refractive index of air and the refractive index of a third material for forming an MLA, in absence of the moisture-resisting layer, having desired optical properties; identifying said first material and said second material, wherein a ratio between the refractive index of the second material and the refractive index of the first material is substantially the same as the a ratio between the refractive index of air and the refractive index of the third material; and forming the optical device such that optical device has said desired optical properties.

The defined optical properties of the MLA formed of the third material may be the far field beam profile or field of illumination (FOI) of the MLA formed of the third material.

The refractive index of the first material may be greater than the refractive index of the second material.

The plurality of micro-lenses of the MLA may define an MLA height and the MLA may further comprise an edge structure at a periphery of the MLA having an edge structure height which is equal to or greater than the MLA height. The method may further comprise forming the moisture-resisting layer over the edge structure such that a total height of a moisture-resistant MLA portion of the optical device is equal to the edge structure height plus the thickness of moisture-resisting layer formed over the edge structure.

The moisture-resisting layer may form a planar surface of the optical device.

The MLA may be formed on a substrate. The substrate may be formed from glass.

The MLA may form part of a vertical cavity surface emitting laser (VCSEL) wafer formed of said first material. The method may further comprise forming at least one VCSEL emitter in the VCSEL wafer.

There may be an array of VCSEL emitters. Each of the VCSEL emitters may be located beneath a corresponding micro-lens of the MLA.

The first material may be one of: Si, GaAs, Si3N4, SiO, SiN, or SiON.

The second material may be one of: an acrylic material or a modified epoxy resin.

The MLA may be formed by replication/nanoimprint.

The MLA may be formed by writing, for example by direct laser writing.

According to a third aspect of the invention there is provided an optical device manufactured according to the previous aspect of the invention.

The optical device may not include any moisture detection.

According to a fourth aspect of the invention there is provided a method of manufacturing an infra-red illuminator comprising a manufacturing an optical device according to the second aspect of the invention.

According to a fifth aspect of the invention there is provided in illuminator manufactured according to the previous aspect of the invention.

The illuminator may be an infra-red illuminator. That is, it may emit infra-red light and include at least one infra-red light source.

The illuminator may not include any moisture detection.

Prior art optical devices are susceptible to having their operating safety compromised by the presence of moisture or other chemical contamination.

Compared to such known systems, the present moisture-resistant optical device and associated manufacture method disclosed here has the following advantages:
1. Operation of the optical device may not be affected by moisture or chemical contamination on its surface.
2. Safety of the optical device may not be affected by moisture or chemical contamination on its surface.
3. Operation of the optical device may be less adversely affected by an impact on its surface.
4. Safety of the optical device may be less adversely affected by an impact on its surface.
5. The cost/complexity of producing the optical device may be less as moisture detection and/or impact detection may not be required.

Finally, the present moisture-resistant optical device and associated manufacture method disclosed here utilises a novel approach at least in that a moisture-resisting layer of another material is formed on the MLA and fills the associated recesses

### BRIEF DESCRIPTION OF THE DRAWINGS

Some embodiments of the disclosure will now be described by way of example only and with reference to the accompanying drawings, in which:

FIG. 1 shows a schematic cross-sectional view of a prior art optical device;

FIG. 2 shows a schematic cross-sectional view of an optical device in accordance with an embodiment of the present invention;

FIG. 3 shows some example, simulated intensity plots for light transmitted by i) an illuminator including a prior art optical device and ii) an illuminator including an optical device according to an embodiment of the present invention;

FIG. 4 shows a schematic cross-sectional view of an optical device in accordance with another embodiment of the present invention; and

FIG. 5 shows a schematic cross-sectional view of an optical device in accordance with a further embodiment of the present invention.

Equivalent features within the figures have been given the same reference numerals.

### DETAILED DESCRIPTION OF THE PREFERRED EMBODIMENTS

Generally speaking, the disclosure provides a moisture-resistant optical device (and associated method) comprising a microlens array (MLA) formed from a first material defining a plurality of associated recesses; and a moisture-resisting layer of a second material, formed on the MLA and filling the associated recesses.

Some examples of the solution are given in the accompanying figures.

Embodiments of the present disclosure can be employed in many different applications including digital recorders, for example, in portable computing devices and other industries.

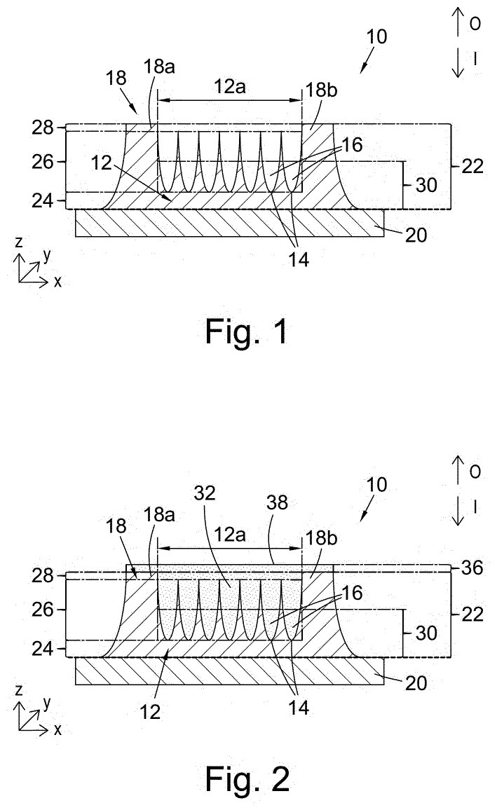

FIG. 1 shows a schematic cross-sectional view of a known optical device 10. The optical device 10 comprises a microlens array (MLA) 12. The MLA takes the form of an orthogonal XY array (extending along orthogonal X and Y axes) of microlenses. The present example shows a cross-section through seven microlenses (two of which are indicated by 14) along the X axis. The microlenses 14 each have the same structure and are formed as concave lenses. It will be appreciated that, in this prior art example and in any of the embodiments of the invention discussed below, that the MLA may include any appropriate number of microlenses in either the X or Y direction (for example, many more than seven). In some MLAs there may be an equal number of microlenses in the X direction and in the Y direction. In other MLAs the number of microlenses in the X direction and the Y direction may be different. In addition, the number of microlenses in the X direction may be different at different Y positions, and the number of microlenses in the Y direction may be different at different X positions. Furthermore, whilst all the microlenses in the shown example are identical and concave. In other MLAs the microlenses need not be identical throughout the array. Furthermore in other MLAs the microlenses may be of any other appropriate lens type, for example convex.

The MLA 12 defines a plurality of associated recesses. In this example, given that the microlenses 14 are concave, each microlens 14 itself defines a cavity or recess—seven are shown in the figure and two of which are labelled 16. In other examples, for example, where the microlenses are convex, the associated recesses may be formed between adjacent microlenses.

The MLA 12 also includes an edge structure 18 at a periphery of the MLA 12. Given that the MLA 12 is an XY array the edge structure 18 takes the form of a generally quadrilateral wall. Two sidewall portions 18a, 18b of the edge structure 18 are visible in the figure.

A clear aperture 12a of the MLA 12 is defined between facing sides of the edge structure 18.

The MLA 12 is formed of a first material on a generally planar substrate 20 formed of a substrate material.

The material from which the MLA 12 is formed may be any appropriate material. Appropriate materials will be determined, at least in part, by the wavelength(s) of light with which the optical device is to be used. For example, the appropriate material will have sufficient optical transmission at the wavelength(s) concerned, such that the relevant light can pass through the optical device without an unacceptable amount of loss. Examples of suitable materials, particularly of use for light in the visible and infra-red parts of the electromagnetic spectrum, include: Si, GaAs, Si₃N₄, SiO, SiN, or SiON. The refractive indices of these materials at a wavelength of 940 nm are Si: n=3.59; GaAs: n=˜3.5; Si₃N₄: n=2.01; SiO: n=1.91; SiN: n=1.887; and SiON: n=1.85.

The substrate material may be any appropriate material. Again, appropriate materials will be determined, at least in part, by the wavelength(s) of light with which the optical device is to be used. For example, the appropriate material will have sufficient optical transmission at the wavelength(s) concerned, such that the relevant light can pass through the optical device without an unacceptable amount of loss. An example of a suitable substrate material, particularly of use for light in the visible and infra-red parts of the electromagnetic spectrum, is glass.

The height of various portions of the optical device 10 is measured along the Z axis (which is orthogonal to both the X and Y axes). The total MLA height 22, which is the height of the edge structure, is the sum of a base layer height 24, an MLA height 26 and an offset height 28. The base layer height 24 is the distance between the base of the MLA and the lowest point of the structure of the microlenses 14. The MLA height 26 is the distance between the lowest point of the structure of the microlenses 14 and the highest point of the structure of the microlenses 14. The offset height 28 is the distance between the highest point of the structure of the microlenses 14 and the upper surface of the edge structure 18. For completeness, an MLA centre plane height 30 is defined as the sum of the base layer height 24 plus half the MLA height 26. In the present example, the sum of the MLA height 26 and the base layer height 24 is less than the height of the edge structure 18, such that there is an offset 28. However, in some examples the sum of the MLA height 26 and the base layer height 24 is the same as the height of the edge structure 18, such that there is no offset.

When the optical device 10 forms part of an illuminator, the illuminator may include one or more light sources located above the MLA 12. In other embodiments, as discussed in more detail at a later point in this document, the one or more light sources may be located in the MLA beneath the microlenses.

In some embodiments each light source may be located above or beneath a corresponding microlens of the MLA. In use, the light emitted by the one or more light sources may travel through the optical device in the direction O or in a direction opposite to direction O: direction I. When the optical device forms part of an illuminator, the optical device may take the form of a diffuser.

In some applications, a one or more detectors may be located below the substrate (and/or MLA) or, alternatively, above the MLA. The one or more detectors may be in addition to or alternative to one or more light sources, such as those discussed above. In some embodiments each detector may be located above or beneath a corresponding microlens of the MLA. In embodiments which include one or more detectors, light from beyond the optical device (i.e. from the side of the device closest to the lowest point of the structure of the microlenses) propagates through the optical device in the direction O to the one or more detectors.

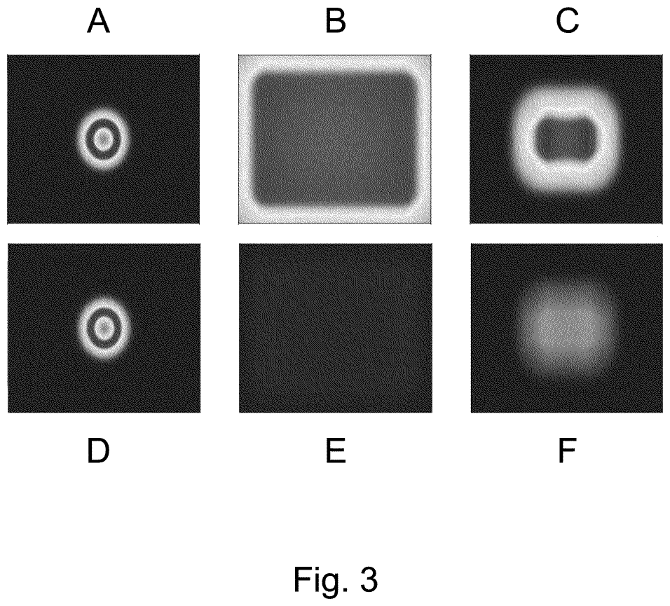

In use, it has been found that moisture (water) and/or other chemical contaminants can collect in the recesses 16. Given that the moisture and/or other chemical contaminants have a refractive index which is different to air (e.g. air has a refractive index of approximately 1 and water has a refractive index of approximately 1.33 at a wavelength of 940 nm) and given that the MLA is designed to function in air, the presence of moisture and/or other chemical contaminants in the recesses affects the optical properties of the optical device. As discussed in more detail in relation to FIG. 3, this can have an adverse effect on the operation of a device of which the optical device forms part.

FIG. 2 shows a schematic cross-sectional view of an optical device 10a in accordance with an embodiment of the present invention.

The optical device 10a of FIG. 2 is identical to that of FIG. 1 except that it includes a moisture-resisting layer 32 of a second material, formed on the MLA 12 and filling the associated recesses 16.

The material from which the moisture-resisting layer 32 is formed may be any appropriate material. As already discussed, appropriate materials will be determined, at least in part, by the wavelength(s) of light with which the optical device is to be used. For example, the appropriate material will have sufficient optical transmission at the wavelength(s) concerned, such that the relevant light can pass through the optical device without an unacceptable amount of loss. Examples of suitable materials, particularly of use for light in the visible and infra-red parts of the electromagnetic spectrum, include: an acrylic material or a resin material, such as a modified epoxy resin.

The refractive index of the material of the MLA 12 may be greater than the refractive index of the material of the moisture-resisting layer 32. In particular, the refractive index of the material of the MLA 12 may be greater than the refractive index of the material of the moisture-resisting layer 32 at the wavelength(s) with which the optical device is intended to be used. For example, the refractive indices of some suitable materials for the MLA, at a wavelength of 940 nm, are Si: n=3.59; GaAs: n=˜3.5; Si₃N₄: n=2.01; SiO: n=1.91; SiN: n=1.887; and SiON: n=1.85. The refractive index of some suitable materials for the moisture-resisting layer, at a wavelength of 940 nm, are an acrylic material: n=1.50; and a modified epoxy resin: n=1.55. Examples of suitable materials may be said to have a low refractive index, for example n≥2, n≥1.8 or n≥1.6.

The moisture-resisting layer 32 is formed over the edge structure 18 such that a total height 34 of a moisture-resistant MLA portion (the moisture-resistant MLA portion of the optical device includes both the MLA 12 and moisture-resisting layer 32) of the optical device is equal to the edge structure height 22 plus the thickness 36 of the moisture-resisting layer 32 formed over the edge structure 18.

The moisture-resisting layer 32 forms a planar (upper) surface 38 of the optical device 10a. The upper surface 38 is the surface of the optical device 10a which is closest to the highest point of the structure of the microlenses 14 of the MLA 12. It is the surface of the optical device 10a via which light travelling in direction I will enter the optical device, and via which light travelling in the direction O will exit the device.

It will be appreciated that, as compared to a prior art optical device 10, such as that shown in FIG. 1, the presence of the additional moisture-resisting layer 32, having a refractive index which is greater than air, as part of the optical device in accordance with the present invention, will affect the optical properties of the optical device 10a. For example, the presence of the additional moisture-resisting layer 32 may affect the field of illumination (FOI) or far field beam profile produced by the optical device.

In some applications it may be desirable to control the optical properties of the MLA 12 and moisture-resisting layer 32 to ensure that the optical properties of the optical device according to the present invention, which includes a moisture-resisting layer, are as similar as possible to (or substantially identical to) to optical properties of an equivalent optical device that does not include a moisture-resisting layer.

In such applications, the optical device without a moisture-resisting layer, having the desired optical properties, has an MLA formed from a reference material such that there is a reference ratio between the refractive index of air and the refractive index of the reference material. In order to achieve an optical device according to the present invention, which includes a moisture-resisting layer, which has the same optical properties as the equivalent optical device without the moisture-resisting layer, the refractive indices of the material from which the MLA is formed and the material from which the moisture resisting layer is formed may be chosen such that the ratio between the refractive index of the material from which the moisture resisting layer is formed and the refractive index of the material from which the MLA is formed is the same as the reference ratio.

The effect of the invention is now discussed in relation to FIG. 3. FIG. 3 shows some example, simulated intensity plots for light transmitted by i) an illuminator including a prior art optical device and ii) an illuminator including an optical device according to an embodiment of the present invention.

In particular, each plot shows the irradiance (or intensity) of light that falls on a detector located 10 cm away from the illuminator vs XY position. Plots A, B and C use a normalised scale (i.e. a scale that is normalised to the maximum value for each plot), whereas plots D, E and F use a common scale (i.e. a scale that is the same for all three plots).

Plots A and D show the irradiance of light produced by a light source that is incident on the detector in absence of any optical device between the light source and the detector. In this example, the light source takes the form of a vertical cavity surface emitting laser (VCSEL) of the type discussed later within this document with reference to FIG. 5. The high irradiance of the light (in particular, in the ring-shaped region) may present a safety risk to the human eye in that it is at a level that may damage the eye.

Plots B and E show the irradiance of light produced by the same light source used in relation to plots A and D. However, in this case a known optical device of the type shown in FIG. 1 is located between the light source and the detector. The optical device has a MLA configuration such that it operates as a diffuser. As can be seen in plot B the optical device causes the irradiance to be relatively uniform over a generally rectangular area with the irradiance decreasing around the edges. As can be seen in plot E, the maximum irradiance on the common scale is much less than that for the light source in absence of the optical device (shown in plot D). The optical device in the form of a diffuser has significantly reduced the irradiance of the light produced by the light source to the extent that the light produced by the light source is safe to the human eye. As such, the optical device in the form of a diffuser is functioning as required.

Plots C and F show the irradiance of light produced by the same light source and optical device used in relation to plots B and E. However, in this case, a thin film of water is present on the outer surface of (and hence in the recesses of) the MLA of the optical device. The presence of the film of water changes the optical properties of the optical device. In particular, the MLA of the optical device causes less refraction of the light produced by the light source and results in the irradiance plots as shown. Plot C shows that, in this scenario, the irradiance is more concentrated to the centre of the detector as compared to that in the absence of a water film, as shown in plot B. Plot F shows that, as compared to the results in the absence of a water film, the maximum irradiance when a film of water is present on the optical device is increased. It follows that the optical device in the form of a diffuser is no longer functioning as required—the maximum irradiance has increased, as compared to when the diffuser is working correctly (in particular, in the central generally lozenge shaped region), to a level that may present a safety risk to the human eye.

It is this increase in maximum irradiance caused by the reduced refraction of the MLA of the optical device (as a result of the presence of water on the surface of the optical device) that the moisture-resisting layer according to the present invention prevents.

Given the effect of the present invention, if the irradiance of light produced by the same light source as already discussed, with an optical device according to the present invention between the light source and the detector, where a film of water is also present on the surface of the moisture-resisting layer, were to be plotted, it would be substantially the same as that shown in plots B and E. As such, the optical device according to the present invention continues to function correctly even with a film of water on the surface of the optical device. That is to say, the maximum irradiance of light produced by the light source which passes through the optical device according to the present invention remains at a level which is safe for the human eye.

In the past, where known optical devices of the type shown in FIG. 1 were used in applications where maximum irradiance levels are safety critical, the optical device may have included a moisture detector. The way in which such a moisture detector functions is not important to understanding of the functioning of the present invention, suffice to say that the detector detects the presence of moisture on the surface of the optical device and, if moisture was detected, provides an output which caused the apparatus of which the optical device forms part to be deactivated or operated at a reduced power level to ensure that unsafe levels of maximum irradiance were not produced due to water being present on the surface of the MLA of the optical device.

Given that operation of an optical device according to the present invention is not adversely affected by (i.e. such that maximum irradiance levels are significantly increased) the presence of water, the moisture detection used for the known optical devices is not necessary for optical devices according to the present invention. By not having to include any form of moisture detection, not only is the manufacturing process for an optical device according to the present invention made more straightforward and less costly, but also operation of a device including an optical device according to the present invention is more straightforward.

It will be appreciated that the present invention, which relates to the inclusion of a moisture resisting layer, is applicable regardless of the way in which the optical device, and in particular the MLA of the optical device, is manufactured. Several examples are discussed below.

The MLA of the prior art optical device in FIG. 1 and the embodiment of the optical device shown in FIG. 2 has been manufactured by replication or nanoimprint using, for example, conformal mould duplication. In these examples the MLA 12 has been formed on a substrate.

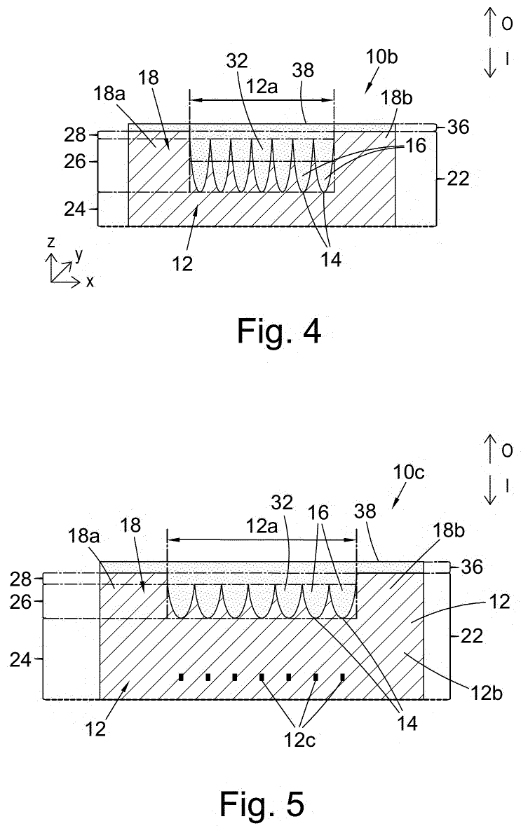

The optical device 10b according to another embodiment of the present invention shown in FIG. 4 differs from those shown in FIGS. 1 and 2 in that it does not include a substrate. In this example the MLA 12 has been formed by writing the structure of the MLA directly into a wafer of the MLA material. The MLA structure may be written by any appropriate method such as direct laser writing or lithography.

The optical device 10c according to a further embodiment of the present invention shown in FIG. 5 also does not include a substrate. In this embodiment the MLA 12 is formed by writing the structure of the MLA directly into a vertical cavity surface emitting laser (VCSEL) wafer 12b. The VCSEL wafer 12b includes a plurality of VCSEL emitters 12c formed in the VCSEL wafer 12b. In the present example, the VCSEL emitters are formed as an array such that each VCSEL emitter is located beneath a corresponding micro-lens of the MLA. This need not always be the case. An anode and cathode (not shown) are located at a base of the VCSEL wafer 12b in order to provide electrical power to the emitters 12c.

The manner in which VCSEL arrays are manufactured and operated is well known in the art and is not critical to the understanding of the present invention. As such, further discussion of this is omitted for the purposes of brevity.

It should be noted that the effect of the present invention is not affected by the direction of propagation of light through the optical device. For example, an optical device according to the present invention may form part of an illuminator in a manner such that, as shown in FIGS. 2 and 4, the one or more light source(s) of the illuminator are located above the optical device (or above the MLA of the optical device), such that light emitted by the one or more light source(s) of the illuminator passes through the optical device in the direction I. Alternatively, an optical device according to the present invention may form part of an illuminator in a manner such that, as shown in FIG. 5, the one or more light source(s) of the illuminator are located below the MLA of the optical device, such that light emitted by the one or more light source(s) of the illuminator passes through the optical device in direction I, opposite to said direction of light passing through the optical device in the embodiments shown in FIGS. 2 and 4.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

1. A moisture-resistant optical device comprising:
a microlens array (MLA) formed from a first material defining a plurality of associated recesses; and
a moisture-resisting layer of a second material, formed on the MLA and filling the associated recesses.

2. The optical device according to claim 1, wherein the optical device has defined optical properties; and
wherein a ratio between refractive indices of the second and first materials is substantially the same as a ratio between air and a third material that would have been required to implement an MLA formed from the third material, in absence of the moisture-resisting layer, having said defined optical properties.

3. The optical device according to claim 1, wherein the refractive index of the first material is greater than the refractive index of the second material.

4. The optical device according to claim 1, wherein the plurality of micro-lenses of the MLA define an MLA height and the MLA further comprises an edge structure at a periphery of the MLA having an edge structure height which is equal to or greater than the MLA height; and wherein the moisture-resisting layer is formed over the edge structure such that a total height of a moisture-resistant MLA portion of the optical device is equal to the edge structure height plus the thickness of moisture-resisting layer formed over the edge structure.

5. The optical device according to claim 1 wherein the moisture-resisting layer forms a planar surface of the optical device.

6. The optical device according to claim 1, wherein the MLA is formed on a substrate.

7. The optical device according to claim 1, wherein the MLA forms part of a vertical cavity surface emitting laser (VCSEL) wafer formed of said first material, wherein at least one VCSEL emitter is formed in the VCSEL wafer.

8. The optical device according to claim 1, wherein the first material is one of: Si, GaAs, Si₃N₄, SiO, SiN, or SiON.

9. The optical device according to claim 1, wherein the second material is one of: an acrylic material or a modified epoxy resin.

10. An illuminator comprising an optical device according to claim 1.

11. A method of manufacturing a moisture-resistant optical device, the method comprising:
forming a microlens array (MLA), defining a plurality of associated recesses, from a first material;
forming a moisture-resisting layer of a second material on the MLA, said moisture-resisting layer filling the associated recesses.

12. The A method of manufacturing an optical device according to claim 11, further comprising:
determining a ratio between the refractive index of air and the refractive index of a third material for forming an MLA, in absence of the moisture-resisting layer, having desired optical properties;
identifying said first material and said second material, wherein a ratio between the refractive index of the second material and the refractive index of the first material is substantially the same as the ratio between the refractive index of air and the refractive index of the third material; and
forming the optical device such that optical device has said desired optical properties.

13. The method of manufacturing an optical device according to claim 11, wherein the refractive index of the first material is greater than the refractive index of the second material.

14. The method of manufacturing an optical device according to claim 11, wherein the plurality of micro-lenses of the MLA define an MLA height and the MLA further comprises an edge structure at a periphery of the MLA having an edge structure height which is equal to or greater than the MLA height;
the method further comprising forming the moisture-resisting layer over the edge structure such that a total height of a moisture-resistant MLA portion of the optical device is equal to the edge structure height plus the thickness of moisture-resisting layer formed over the edge structure.

15. The method of manufacturing an optical device according to claim 11 wherein the moisture-resisting layer forms a planar surface of the optical device.

16. The method of manufacturing an optical device according to claim 11, wherein the MLA is formed on a substrate.

17. The method of manufacturing an optical device according to claim 11, wherein the MLA forms part of a vertical cavity surface emitting laser (VCSEL) wafer formed of said first material,
the method further comprising forming at least one VCSEL emitter in the VCSEL wafer.

18. The A method of manufacturing an optical device according to claim 11, wherein the first material is one of: Si, GaAs, Si₃N₄, SiO, SiN, or SiON.

19. The method of manufacturing an optical device according to claim 11, wherein the second material is one of: an acrylic material or a modified epoxy resin.

20. An optical device manufactured according to the method of claim 11.

21. A method of manufacturing an infra-red illuminator comprising manufacturing an optical device according to claim 11.

22. An illuminator manufactured according to the method of claim 21.
